(19) United States
(12) Patent Application Publication
(10) Pub. No.: US 2008/0237822 A1
(43) Pub. Date: Oct. 2, 2008

(54) Microelectronic die having nano-particle containing passivation layer and package including same

(76) Inventors: Nachiket R. Raravikar, Chandler, AZ (US); Sumant Padiyar, Chandler, AZ (US); Neha Patel, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/731,524

(22) Filed: Mar. 30, 2007

(51) Int. Cl. H01L 23/29

(52) U.S. Cl. 257/684; 977/775; 257/E23.117

(57) ABSTRACT

A microelectronic die and a package including the die. The die comprises a die substrate including a base and a die passivation layer disposed on the base. The die passivation layer includes a nanocomposite including a matrix and nanoparticles dispersed within the matrix.

### FIELD

Embodiments of the present invention relate generally to the field of microelectronic fabrication. In particular, embodiments relate to a passivation structure for a microelectronic substrate.

### BACKGROUND

Microelectronic dies typically including build-up metal layers (also known as back-end layers) on front end devices such as transistors, capacitors and the like. The dies include a die substrate usually made of silicon, such as single crystal silicon, and one or more metallization layers that allow the integration of various components, such as the front end devices mentioned above. Microelectronic substrates onto which dies are usually mounted, such as, for example, by way of C4 solder bumping, wire-bonding, or the like to form a microelectronic package, typically include an organic or ceramic package substrates which may include build-up metal layers (also known as substrate metal build-up layers), vias, and trenches. For the purposes of the instant disclosure, the substrate of the microelectronic die will hereinafter be referred to as the “die substrate,” and the substrate onto which the die is to be mounted to form a microelectronic package will be referred to as the “package substrate.” The final layer typically deposited on a die/package substrate includes a passivation layer which is an insulating layer that provides protection against mechanical and chemical damage during assembly and packaging. Where this passivation layer is on the package substrate, it is sometimes also referred to as a solder resist layer.

An example of a conventional die passivation structure is shown schematically in FIG. 1. FIG. 1 shows a detail of a portion of a die substrate 102 having formed on its outer surface a metal interconnect layer 103 which includes a contact pad 124 and interconnects 106. A die passivation layer 108, which may include a layer made of polymeric resin, such as, for example, a polyimide or epoxy novolac based photoresist material, is formed over base 105. A contact opening 114 is then formed through the die passivation layer 108 to enable an electrical contact be made to contact pad 124 by way of reflowing solder balls in a well known manner to enable the inputting and outputting of external signals to the die substrate. The contact opening 114 is typically formed by way of lithography in a well known manner.

Although such a passivation structure provides an excellent hermetic seal of die substrate 102, device performance suffers. This is because passivation layers of the prior art tend to crack during and post assembly (including during all assembly steps, such as during chip attach, during underfill provision and/or IHS provision). In the case of a package substrate, package substrate vias and trenches may crack. In the case of a die substrate, assembly stresses may sometimes cause cracking of the die passivation layer, which may crack the ILD layer underneath. Disadvantageously, the above problem is exacerbated as the diameter of solder bumps necessary for die attach decreases. Currently, the state of the art uses 105 micron bumps, but subsequent technologies are looking to using smaller bumps such as one having a diameter of about 90 microns or less. The above results in higher stresses on the die substrate and/or package substrate passivation structures. Another disadvantage of the prior art is that current die passivation structures show poor adhesion with various materials they are in contact with, such as with copper bumps of the die, with epoxy underfill materials sometimes used in mounting the die to a package substrate, and with the die ILD. Current package substrate passivation structures further show poor adhesion with various materials they are in contact with, such as with the epoxy underfill materials mentioned above. Poor adhesion as occurs with prior art passivation structures lead to further crack propagation and delamination across the passivation interfaces, in this way affecting device performance.

The prior art has proposed adding toughening agents, such as, for example, rubber elastomeric particles, to the passivation materials. However, disadvantageously, the above has been shown to lead to a reduction in passivation structure stiffness and reduction in adhesion to other materials. Stiffness is desirable for the overall dimensional stability of the passivation layer. A low stiffness passivation layer could plastically yield relatively easily, even under relatively small stresses, leading to changes in the dimensions of the bump openings on the die or package substrates.

The prior art fails to provide a robust die/package substrate passivation structure that is crack resistant under thermo-mechanical stresses and that further shows adequate adherence to the materials it is in contact with post chip attach.

### BRIEF DESCRIPTION OF THE DRAWINGS

FIG. 1 is a schematic cross-sectional view of a prior art die passivation structure;

FIG. 2 is a schematic view of a microelectronic package including a die passivation layer according to embodiments;

FIG. 3 is a schematic view of a detail of the passivation layer of FIG. 2 according to a first embodiment;

FIG. 4 is a schematic view of a detail of the passivation layer of FIG. 2 according to a second embodiment;

FIGS. 5a-5c are schematic views of the material of the passivation layer of FIG. 4 undergoing self-healing;

FIG. 6 is a schematic view of a detail of the passivation layer of FIG. 2 according to a third embodiment; and

FIG. 7 is a schematic view of an embodiment of a system incorporating a microelectronic package as shown in FIG. 2.

For simplicity and clarity of illustration, elements in the drawings have not necessarily been drawn to scale. For example, the dimensions of some of the elements may be exaggerated relative to other elements for clarity. Where considered appropriate, reference numerals have been repeated among the drawings to indicate corresponding or analogous elements.

### DETAILED DESCRIPTION

In the following detailed description, a microelectronic die including a nanocomposite passivation layer, and a package and a system including the die are disclosed. Reference is made to the accompanying drawings within which are shown, by way of illustration, specific embodiments by which the present invention may be practiced. It is to be understood that other embodiments may exist and that other structural changes may be made without departing from the scope and spirit of the present invention.

The terms on, above, below, and adjacent as used herein refer to the position of one element relative to other elements. As such, a first element disposed on, above, or below a second element may be directly in contact with the second element or it may include one or more intervening elements. In addition, a first element disposed next to or adjacent a second element may be directly in contact with the second element or it may include one or more intervening elements. In addition, in the instant description, figures and/or elements may be referred to in the alternative. In such a case, for example where the description refers to Figs. X/Y showing an element A/B, what is meant is that Fig. X shows element A and Fig. Y shows element B. In addition, a “layer” as used herein may refer to a layer made of a single material, a layer made of a mixture of different components, a layer made of various sub-layers, each sub-layer also having the same definition of layer as set forth above.

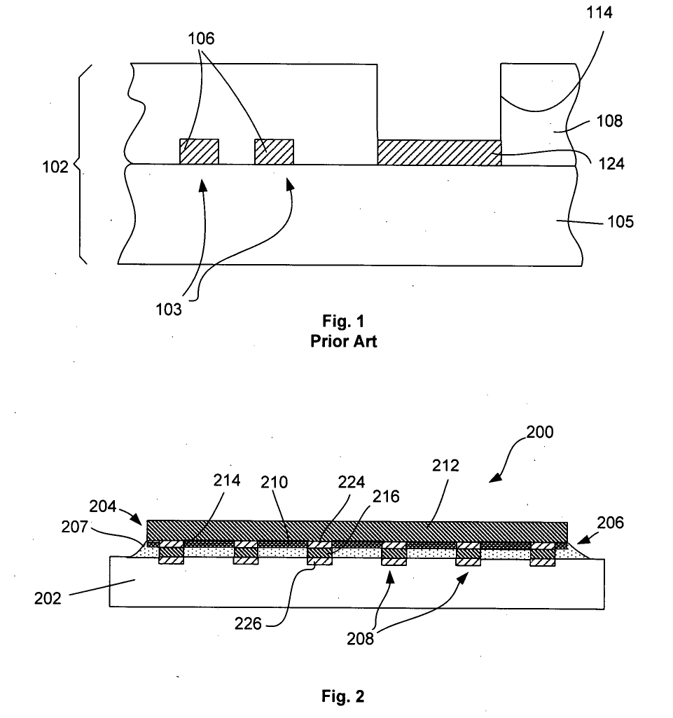

Aspects of this and other embodiments will be discussed herein with respect to FIGS. 2-7 below. The figures, however, should not be taken to be limiting, as it is intended for the purpose of explanation and understanding.

Referring first to FIG. 2, a microelectronic package 200 is shown according to an embodiment. Package 200 includes a substrate 202, and a die 204 bonded to the substrate by a bond 206. As seen in FIG. 2, a plurality of joint structures 208 are shown between the die 204 and the substrate 202, the joint structures 208 forming at least part of bond 206. Optionally, the bond 206 may also include an underfill material 207 provided in a well known manner. Referring still to FIG. 2, the joint structures 208 include contact pads 224 on the die 204, and bond pads 226 on the substrate. As is well known the contact pads 224 and bond pads 226 allow an electrical bonding of the die and substrate, respectively, to external circuitry. It is noted that, although the contact pads 224 and bond pads 226 are shown as a single layer, it is understood that, in the context of the instant description, they not only include the metallization layers of the die/substrate proper to enable external electrical contact, but also the under bump metallization (such as, for example, ENIG, etc.) provided on the metallization layers. As further shown in FIG. 2, joint structures 208 further comprise solidified solder 216 bonding the die 204 and the substrate 202 to one another in a well known manner. A die passivation layer 210 is shown as having been disposed on a die substrate 212, the die passivation layer defining contact openings 214 therethrough. Contact opening 214 is defined through the die passivation layer 210 to enable an electrical contact, such as solder 216, to be made to contact pads 224 to enable the inputting and outputting of external signals to the die substrate 212. The contact opening 214 may be formed in a well known manner, such as, for example, by way of lithography.

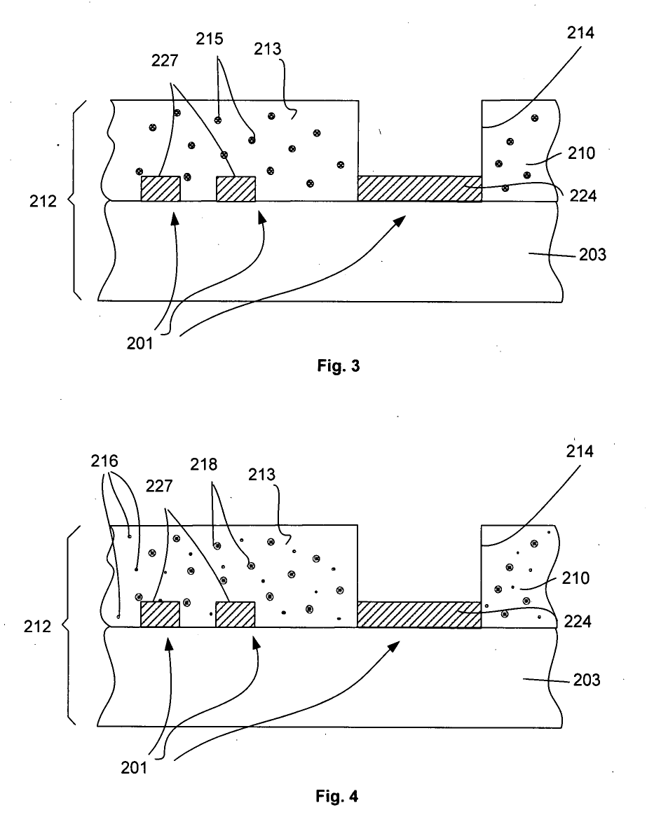

According to embodiments, the die passivation layer 210 includes a nanocomposite material including a matrix and nanoparticles dispersed within the matrix. According to embodiments, the matrix may include a polymer, such as, for example, epoxy, or, preferably polyimide. The polymer may include, for example, any of the well known polymers known to be used as the material for die/package substrate passivation layers. According to a first embodiment, as will be explained in further detail with respect to FIG. 3, the nanoparticles within the matrix may include coated nanoparticles, such as, for example, silane-coated nanoparticles. According to a second embodiment, as will be explained in further detail with respect to FIG. 4, the nanoparticles within the matrix may include catalyst nanoparticles, the nanocomposite of the passivation layer then further including self-healing capsules dispersed within the matrix. The above two embodiments will be described below with respect to FIGS. 3 and 4, respectively.

Referring now to FIG. 3, a schematic detail is shown depicting the die passivation layer 210 of FIG. 2 according to a first embodiment. Here, a detail of die substrate 212 is shown prior to its bonding with package substrate 202. A metallization layer 201 on the die substrate 212 includes contact pads 224 and interconnects 227. The die substrate 212 includes a base 203 and the die passivation layer 210 disposed on the base 203. Here, the die passivation layer 210 nanocomposite material includes a matrix 213 within which are dispersed coated nanoparticles 215 as fillers. Preferably, the nanoparticles 215 include coated oxide nanoparticles, have a dimension below about 100 nm, and preferably between about 10 nm and about 40 nm. According to a preferred embodiment, the nanoparticles 215 include silane-coated nanoparticles, such as, for example, silane-coated alumina, silica or zirconia nanoparticles. Interface dominates composite properties. Depending upon process and interface considerations, property enhancement of the nanocomposite may be seen at filler loadings of about 0.001% by weight to about 40% by weight, other percentages being within the purview of embodiments. The shown embodiment of the die passivation layer 210 in FIG. 3 may be made, for example, by sonication-based mixing/dispersion of the coated nanoparticles with the matrix material in its uncured form, such as, for example, with an uncured epoxy material, followed by spin coating of the mixture onto the base 203 and in situ curing of the composite in a well known manner. Spin-coating may help to create a desired thickness of the die passivation layer 210 of about 10 microns according to an embodiment. The coating of the nanoparticles, such as, for example, silane-coating, may be needed for better dispersion by sonication, and for creating a strong interface across the nanoparticles and the matrix material. The first embodiment of a die passivation layer 210 as shown in FIG. 3 yield a stiffer material for the passivation layer as compared with die passivation layers of the prior art. Silane-coated nanoparticles may be obtained commercially, for example from Admatechs Corp. Ltd. of Aichi, Japan, Sokang Nano of Beijing, China, Sarastro GmbH of Quierschied-Göttelborn, Germany, and Nanophase Technologies Corporation of Romeoville, Ill., USA, to name a few. In addition, the addition of oxide nanoparticles to polymer is known to increase its stiffness and surface energy. As a result, the increase in the surface energy of the nanoparticle-filled die passivation layer 210 leads to an improvement in its adhesion with materials of the substrate, such as, for example, metals, ceramics and polymers.

Referring next to FIG. 4, a schematic detail is shown depicting the die passivation layer 210 of FIG. 2 according to a second embodiment. Here, similar to FIG. 3, a detail of die substrate 212 is shown prior to its bonding with package substrate 202. A metallization layer 201 on the die substrate 212 includes contact pads 224 and interconnects 227. The die substrate 212 includes a base 203 and the die passivation layer 210 disposed on the base 203. Here, according to a second embodiment, the nanoparticles within the matrix may include catalyst nanoparticles 216, the nanocomposite of the die passivation layer 210 then further including self-healing capsules 218 dispersed within the matrix. By “self-healing capsule,” what is meant in the context of embodiments is a capsule containing a healing agent that is adapted to be released upon crack intrusion into the capsule. By “catalyst nanoparticle,” what is meant is a nano-sized particle that includes a chemical trigger to trigger, upon contact with the healing agent of the self-healing capsule, a conversion of the healing agent into a solid material to bond crack faces. For example, the catalyst nanoparticle may be a nano-sized particle that may include a chemical trigger to trigger, upon contact with the healing agent, a polymerization of the healing agent to bond crack faces. The self-healing capsules may be made of dicyclopentadiene (DCPD) healing agent encapsulated in a Urea Formaldehyde shell. The capsules may be dispersed in a polymer matrix such as epoxy, along with Ruthenium-based Grubb's catalyst particles to initiate ring-opening metathesis polymerization (ROMP) of the self-healing agent such as DCPD. The capsules may be formed using standard microencapsulation techniques. Preferably, the capsules have a size less than about 300 nm, and the catalyst nanoparticles may be between about 1 nm and about 100 nm. According to one embodiment, the self-healing capsules may be made by longer time sonication and/or addition of anti-solvents to cause precipitation of capsules of sizes smaller than about 300 nm. Longer time sonication according to an embodiment would form cavitation-induced micro-bubbles. Longer time will merely intensify the effect, further breaking down any particles that come within the force field of the sonicator, thus resulting in smaller capsules. While prior art microencapsulation methods involve the formation of colloidal suspensions of a self healing liquid surround by a soft shell-like gel, which gel then cures under predetermined temperature and time conditions, an embodiment contemplates applying sonication energy before curing the shell to allow the formation of smaller colloids having thinner shells, in this way resulting in smaller capsules. With respect to the use of an anti-solvent, the anti-solvent would chemically “dislike” the solvent that the colloids are suspended in, such that the colloids prefer this new anti-solvent over their parent solvent. Hence, it would tend to break the colloids into smaller droplets, potentially yielding smaller capsules. Any liquid insoluble in conventional solvents used to create colloidal suspensions of self-healing capsules would work according to an embodiment. The shown embodiment of the die passivation layer 210 in FIG. 4 may be made, for example, by simple, gentle, mechanical mixing, or by sonication-based mixing/dispersion of the capsules and nanoparticles with the matrix material in its uncured form, such as, for example, with an uncured epoxy material, following by spin coating of the mixture onto the base 203 and in situ curing of the composite in a well known manner. Preferably, the capsules are provided at up to about 10% by volume, and the catalyst nanoparticles at about 10% by volume, although embodiments are not so limited. A maximum size of the self-healing capsules contained in the nanocomposite of the second embodiment may be determined by the wavelength of light used in lithography to generate the contact opening 214 through the die passivation layer 210. Typically, the light used in lithography to create the contact opening 214 has a wavelength of about 355 nm. As a result, fillers of sizes less than 355 nm will not scatter this light, and the photodefinability of the passivation layer should therefore not be sacrificed if sonication conditions are tailored such that the capsule size is 300 nm or less. The second embodiment of a die passivation layer 210 as shown in FIG. 4 yields a tough material for the passivation layer, such as, for example, one having a toughness that is over about 100% higher than a toughness of the matrix alone. The self-healing capsules and catalyst nanoparticles may also be obtained for example from the University of Illinois at Urbana Champaigne (UIUC).

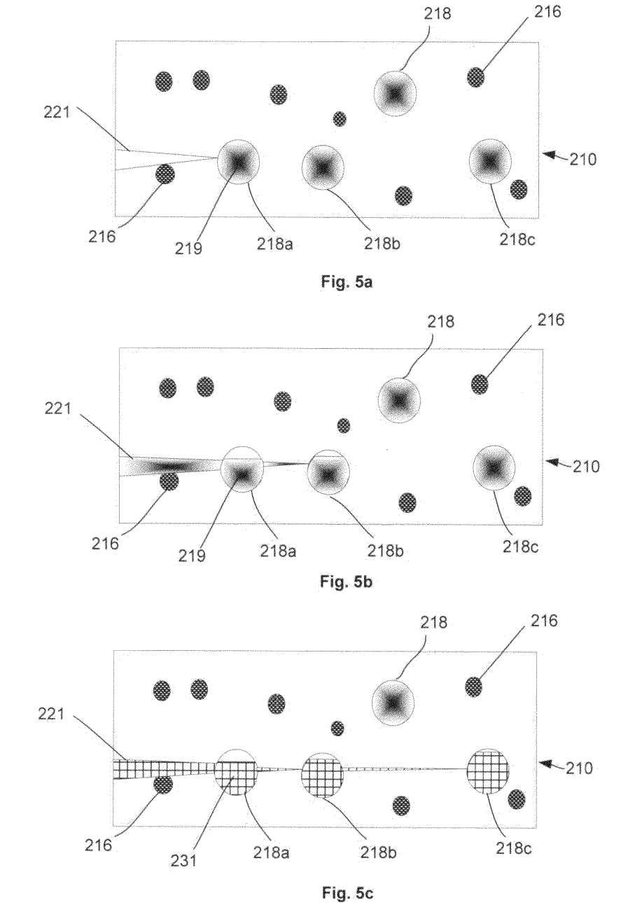

Reference is now made to FIGS. 5a-5c, where a self-healing capability of a detail of the die passivation layer 210 of the embodiment of FIG. 4 is depicted in three different stages. As seen in FIG. 5a, if damage to the die passivation layer 210 should occur, a crack 221 would propagate into the matrix 212 and rupture one or more self-healing capsules along its way, such as capsules 218a, 218b and/or 218c. Since the stress at the tip of the crack, such as crack 221, is high, it can easily rupture the capsules. A liquid resin healing agent 219 inside the capsules will then be released into the crack plane through capillary action as shown in FIG. 5b. As next seen in FIG. 5c, while filling the crack, the healing agent 219 will come across one or more catalyst particles 216, which will initiate polymerization of the healing agent in the crack to form a polymer 231, thus bonding the crack faces closed, and arresting the crack from propagating.

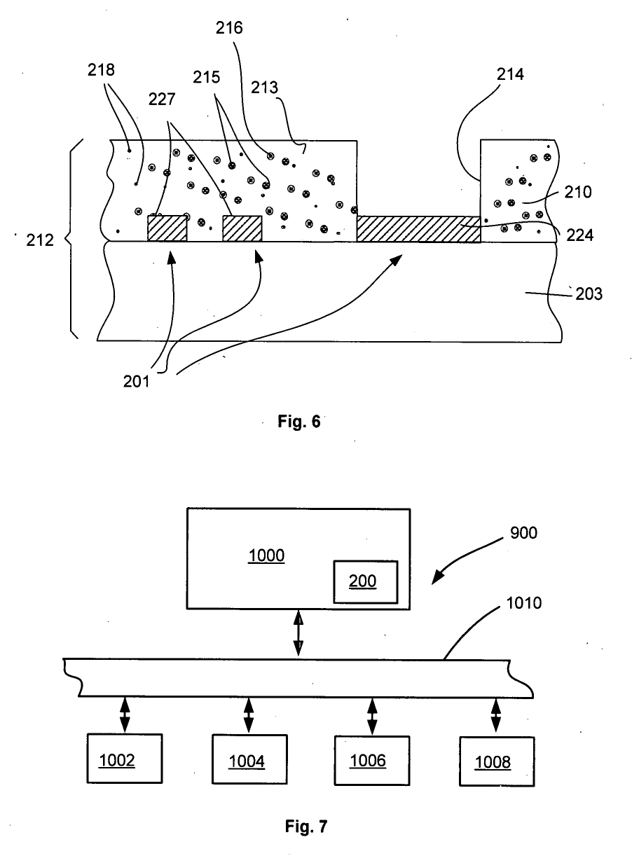

Referring now to FIG. 6, a schematic detail is shown depicting the die passivation layer 210 of FIG. 2 according to a third embodiment. Here, a detail of die substrate 212 is shown prior to its bonding with substrate 202. A metallization layer 201 on the die substrate 212 includes contact pads 224 and interconnects 227. The die substrate 212 includes a base 203 and the die passivation layer 210 disposed on the base 203. Here, the die passivation layer 210 nanocomposite material includes a matrix 213 within which are dispersed fillers including: coated nanoparticles 215 (similar to the coated nanoparticles 215 of FIG. 3), and, in addition, catalyst nanoparticles 216 (similar to the catalyst nanoparticles 216 of FIG. 4) and self-healing capsules 218 (similar to the self-healing capsules 218 of FIG. 4). The embodiment of FIG. 6 is therefore a combination of the embodiments of FIGS. 3 and 4. According to an embodiment, the die passivation layer 210 of FIG. 6 may include up to about 20% by volume of the fillers as noted above. For example, according to one embodiment, a stiff yet tough die passivation layer 210 may be made by first mixing silane treated silica, zirconia or alumina nanoparticles into an uncured matrix resin by way of sonication, followed by the addition of self-healing capsules and catalyst nanoparticles into the mixture by way of either gentle, simple mixing or by way of sonication. The thus obtained mixture may then be spin coated onto the base 203 followed by in situ cure of the mixture.

Advantageously, embodiments provide an improved die passivation layer including nanoparticles which addresses issues regarding interfacial as well as bulk failure of such passivation layers seen in the prior art. A first embodiment such as described above with respect to FIG. 3 advantageously provides a stiff, scratch resistant passivation layer that shows improved adhesion to metals, ceramics and polymers. The second embodiments such as described with respect to FIGS. 4 and 5a-5c above advantageously provides a tough, fracture resistant passivation layer. The third embodiment, which is a combination of the embodiments of FIGS. 3 and 4, as described above with respect to FIG. 6 advantageously combines the advantages cited with respect to the embodiments of FIG. 3 on the one hand, and of FIGS. 4 and 5a-5c on the other hand.

Although embodiments as noted above have been described in relation to a die passivation layer, embodiments include within their scope a package substrate passivation layer, and in particular a solder resist passivation layer, which has any of the same compositions as set forth above with respect to the figures.

The various embodiments described above have been presented by way of example and not by way of limitation. Having thus described in detail embodiments of the present invention, it is understood that the invention defined by the appended claims is not to be limited by particular details set forth in the above description, as many variations thereof are possible without departing from the spirit or scope thereof.

What is claimed is:

1. A microelectronic die comprising a die substrate including a base and a die passivation layer disposed on the base, the die passivation layer comprising a nanocomposite including a matrix and nanoparticles dispersed within the matrix.

2. The die of claim 1, wherein the matrix comprises a polymer.

3. The die of claim 2, wherein the nanoparticles include silane-coated nanoparticles.

4. The die of claim 3, wherein the nanoparticles include at least one of zirconia, silica, zirconia and alumina nanoparticles.

5. The die of claim 2, wherein the nanoparticles include catalyst nanoparticles, the nanocomposite further including self-healing capsules dispersed within the matrix.

6. The die of claim 5, wherein the self-healing capsules include a urea formaldehyde capsule containing a dicyclopentadiene healing agent therein.

7. The die of claim 5, wherein the catalyst nanoparticles comprise Grubb's Ru.

8. The die of claim 5, wherein the self-healing capsules have a diameter of about 300 nm or less.

9. The die of claim 2, wherein the nanoparticles include silane-coated nanoparticles and catalyst nanoparticles, and further wherein the nanocomposite further includes self-healing capsules dispersed within the matrix.

10. The die of claim 9, wherein the silane-coated nanoparticles include at least one of silica, zirconia and alumina nanoparticles.

11. The die of claim 9, wherein the self-healing capsules include a urea formaldehyde capsule containing a dicyclopentadiene healing agent therein.

12. The die of claim 9, wherein the catalyst nanoparticles comprise Grubb's Ru.

13. The die of claim 9, wherein the self-healing capsules have a diameter of about 300 nm or less.

14. A microelectronic package comprising:
a package substrate;
a die bonded to the package substrate, the die comprising a die substrate including a base and a die passivation layer disposed on the base, the die passivation layer comprising a nanocomposite including a matrix and nanoparticles dispersed within the matrix.

15. The package of claim 14, wherein:
the matrix comprises a polymer;
nanoparticles include at least one of silane-coated nanoparticles and catalyst nanoparticles.
